(19) United States
(12) Patent Application Publication
(10) Pub. No.: US 2011/0315223 A1
(43) Pub. Date: Dec. 29, 2011

(54) COATING HAVING IMPROVED HYDROLYTIC RESISTANCE

(75) Inventors: Yuan-Ping Robert Ting, Morristown, NJ (US); Simon Porter, Morristown, NJ (US)

(73) Assignee: HONEYWELL INTERNATIONAL INC., Morristown, NJ (US)

(21) Appl. No.: 13/117,760

(22) Filed: May 27, 2011

Related U.S. Application Data
(60) Provisional application No. 61/358,682, filed on Jun. 25, 2010.
(60) Provisional application No. 61/375,092, filed on Aug. 19, 2010.

(51) Int. Cl. H01L 31/0203; C09J 163/00; C08L 75/04; B32B 27/38

(52) U.S. Cl. 136/259; 428/413; 156/330; 525/453

(57) ABSTRACT

Coatings utilized in multilayer sheets such as laminated films used for photovoltaic backsheets can be prepared by adding epoxy and carbodiimide to a polyurethane mixture to be utilized as the adhesive, prior to application of the coating to a substrate. Such coatings can exhibit improved resistance to hydrolysis, and can maintain bond strength under prolonged conditions of high heat and humidity.

### RELATED APPLICATIONS

This application claims the benefit of U.S. Provisional Application Ser. No. 61/358,682, filed Jun. 25, 2010, currently pending, and U.S. Provisional Application Ser. No. 61/375,092, filed Aug. 19, 2010, currently pending, the disclosures of which are hereby incorporated by reference in their entirety.

### FIELD OF THE INVENTION

The present technology relates to coatings having improved hydrolytic resistance that can be used, for example, as adhesives to adhere a photovoltaic backsheet to a photovoltaic module.

### DESCRIPTION OF RELATED ART

Photovoltaic cells convert sunlight into DC current. A photovoltaic module, also called a photovoltaic panel, is a packaged interconnected assembly of photovoltaic cells. Several photovoltaic modules can be combined to form a photovoltaic array. Photovoltaic modules generally have a backsheet that provides electrical insulation, structural support, and protection from the elements including, for example, UV light and moisture.

To satisfy its intended use, a photovoltaic module must pass various qualification standards, including, for example, standards of the International Electrotechnical Commission (IEC) such as IEC 61215, IEC 61730, and IEC 61646. For example, as set forth in IEC 61215, photovoltaic modules are generally required to pass damp heat testing conducted at a temperature of about 85° C. and a relative humidity of about 85%. The photovoltaic module is subjected to those conditions for 1000 hours, and in order to pass must show no evidence of major visual defects, the degradation of maximum output power cannot exceed 5% of the value measured before the test, and the insulation test and wet leakage current test must meet the same criteria as such tests conducted prior to the damp heat test.

The adhesives commonly used in photovoltaic backsheet laminates are standard polyester-polyol systems chain elongated by use of isocyanate compounds having two or more isocyanate functional groups. Hydrolysis of the adhesive can occur by cleavage of the polyester segments generating an acid group and a hydroxyl group. The acid group then can serve as an acid catalyst to promote further uncontrollable hydrolysis. The hydrolysis therefore undoes the effect on cohesive strength of any chain extension technology used. Previous work, addressed in published European Patent Application No. 2040306 A1, has indicated that use of acid scavengers can stop this acid segment from causing further hydrolysis therefore rendering the polyester-polyol urethane adhesive more resistant to losing cohesive strength on hydrolysis. Simply blocking the acid end-groups formed by hydrolysis of the polyester segments, however, still allows the adhesive polymer backbone to break down. This breakdown not only manifests itself in a cohesive failure of the adhesive it also allows water into the polyester terephthalate dielectric layer in the backsheet. This allows hydrolysis of the dielectric layer to proceed during the high temperature and high humidity testing. The result of this hydrolysis reaction is often observed as an embrittling of the dielectric layer. For example, the present inventors have discovered that the use of acid scavenging moieties alone does not confer long term hydrolytic resistance to exposure of the adhesive to 85° C. at 85% relative humidity. Moreover, the use of acid scavengers in the laminating adhesive does not protect the dielectric layer from hydrolytic embrittlement.

### SUMMARY OF THE INVENTION

Compositions of the present technology can be used, for example, as coatings that can function as adhesives or as protective layers on substrates. In one example, a composition of the present technology can be used as a layer, such as an adhesive layer in a multilayer sheet used to form the backsheet of a photovoltaic cell.

In one aspect, a composition is provided that includes a polyol, an isocyanate, and an epoxy having an epoxy equivalent weight from about 100 g/eq to about 1000 g/eq. The composition can also include a carbodiimide.

In a second aspect, a multilayer sheet is provided that includes at least one first layer, at least one second layer having a first side and a second side, and at least one first layer of a composition of the present technology. The composition can include a polyol, an isocyanate, and an epoxy having an epoxy equivalent weight from about 100 g/eq to about 1000 g/eq. The first layer of the composition can adhere the at least one first layer to the first side of the at least one second layer to form a multilayer sheet, and the average bond strength of a multilayer sheet can be at least about 8 N/cm as measured at a time about 48 hours after the formation of the multilayer sheet. A backsheet for a photovoltaic cell can include the multilayer sheet.

In a third aspect, a method of improving the hydrolytic stability of a composition is provided that includes providing a polyol, providing an isocyanate, mixing the polyol and the isocyanate to form a polyurethane mixture, and adding an epoxy having an epoxy equivalent weight from about 100 g/eq to about 1000 g/eq to the polyurethane mixture to form the composition. The method can also include adding a carbodiimide to the polyurethane mixture.

In a fourth aspect, a method of improving the hydrolytic stability of a multilayer sheet that includes providing a polyol, providing an isocyanate, mixing the polyol and the isocyanate to form a polyurethane mixture, and adding an epoxy having an epoxy equivalent weight from about 100 g/eq to about 1000 g/eq to the polyurethane mixture to form a composition, and forming a multilayer sheet comprising at least one layer of the composition.

In a fifth aspect, a photovoltaic cell comprising a backsheet is provided, where the backsheet includes at least one layer of a composition comprising a polyol, an isocyanate, an epoxy having an epoxy equivalent weight from about 100 g/eq to about 1000 g/eq, and optionally a carbodiimide.

In a sixth aspect, a method of adhering substrates is provided that includes providing a first substrate, providing a second substrate, and applying a layer of a composition between the first substrate and the second substrate to adhere the first substrate to the second substrate. The composition comprises a polyol, an isocyanate, and an epoxy having an epoxy equivalent weight from about 100 g/eq to about 1000 g/eq.

In a seventh aspect, a method of providing a protective layer on a substrate is provided that includes applying a layer of a composition on a substrate, the composition comprising a polyol, an isocyanate, and an epoxy having an epoxy equivalent weight from about 100 g/eq to about 1000 g/eq.

### BRIEF DESCRIPTION OF THE DRAWINGS

Specific examples have been chosen for purposes of illustration and description, and are shown in the accompanying drawings, forming a part of the specification.

FIG. 1 illustrates one example of a five layer multilayer sheet of the present technology.

### DETAILED DESCRIPTION

Compositions of the present technology can by used in many applications, including for example, as coatings and as layers in multilayer sheets.

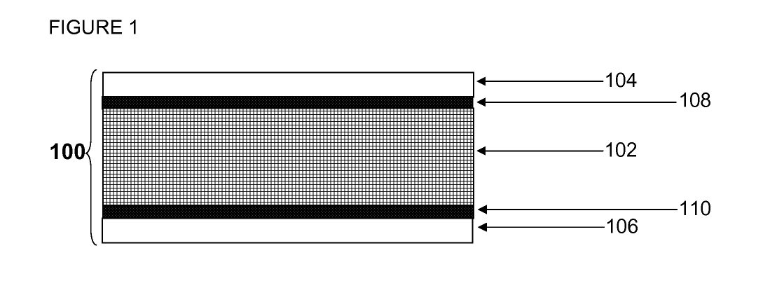

In one example, photovoltaic cells can include a backsheet formed from a multilayer sheet that includes at least one layer of a composition of the present technology. The multilayer sheet can have any suitable number of layers, including for example, the five layer structure illustrated in FIG. 1. As shown in FIG. 1, a multilayer sheet 100 includes a core layer 102 that has a first side and a second side, a first outer layer 104, a second outer layer 106, a first layer of the composition 108, and a second layer of the composition 110. The first layer of the composition 108 and the second layer of the composition 110 can each act as a layer of adhesive. Accordingly, the first layer of the composition 108 can adhere the first outer layer 104 to the first side of the core layer 102, and the second layer of the composition 110 can adhere the second outer layer 106 to the second side of the core layer 102. The multilayer sheet 100 can be made utilizing any suitable equipment, including, for example, a gravure laminator.

In alternative examples, the multilayer sheet 100 can include at least three layers. In one example, a multilayer sheet 100 can have a core layer 102, at least one outer layer, such as first outer layer 104, and a first layer of the composition 108 adhering the outer layer 104 to the first side of the core layer 102. In another example, a multilayer sheet can have core layer 102 having a first side and a second side, a first layer of the composition 108 and a second layer of the composition 110. In some examples, multilayer sheets of the present technology can exhibit improved hydrolytic stability, as well as improved resistance to the transmission of vapors and moisture.

The core layer 102 can include a high dielectric constant such as, for example, a polyethylene terephthalate (PET), a polyethylene naphthenate (PEN), a polybuylene terephthalate (PBT), a polyamide, a polycarbonate, or a fluoropolymer.

The first and second outer layers 104 and 106 can include any suitable material, including but not limited to FEP, PCTFE, PTFE, PVDF, ETFE, PVF, or mixtures thereof. In some examples, one or both of the outer layers 104 and 106 can be made to be substantially opaque to UV light by incorporating therein a suitable pigment.

Generally, adhesives utilized in photovoltaic backsheets can include polyurethanes. Conventional polyurethane adhesives, which can include polyester-polyols or polyether-polyols, can undergo hydrolysis, and thus lose their cohesive strength and therefore their adhesion under testing conditions such as those set forth in the damp heat test of IEC 61215, particularly when subjected to such conditions for extended time periods. Without being bound by any particular theory, it is believed that the hydrolysis is primarily due to breakdown of the polyester linkage, during which a carboxylic acid end group and/or a hydroxyl end group can be generated.

Without being bound by any particular theory, it is believed that compositions of the present technology include a formulation to prevent loss of cohesive strength caused by breakdown of the polyester linkages, and can thus provide increased resistance to hydrolysis. For example, compositions of the present technology may provide improved hydrolytic stability by cross-linking or chain-extending the polymer backbone prior to hydrolysis such that breakage of the polyester segments does not cause premature cohesive failure. If such a cross-linking mechanism could also partly act as an acid scavenging moiety this cohesive strength would last even longer against hydrolysis.

Compositions of the present technology can include a polyurethane comprising a polyol and an isocyanate. In one example, a composition of the present technology can include a polyester-polyol and a di-functional or multi-functional isocyanate. The polyol and the isocyanate can be present in the polyurethane in a ratio from about 50:1 to about 2:1 based upon weight. In some examples, the ratio of polyol and the isocyanate can be from about 20:1 to about 5:1, or from about 15:1 to about 8:1. When preparing compositions of the present technology, the polyol and the isocyanate can be mixed together in an appropriate container to form a polyurethane mixture. A suitable solvent, including but not limited to ethyl acetate, can be used, if desired, to reduce the viscosity of the polyurethane mixture to a desired viscosity. The polyol and the isocyanate can be added to the container one at a time in any order, or simultaneously. Examples suitable polyester-polyols include, but are not limited to, aliphatic dicarboxylic acids such as succinic acid, glutaric acid, pimelic acid, adipic acid, speric acid, sebacic acid, or brasylic acid; aromatic dicarboxylic acids such as isophthalic acid, terephthalic acid, naphthalenic dicarboxylic acid; aliphatic diols such as ethylene glycol, propylene glycol, butanediol, neopentyl glycol, methyl pentanediol, hexandiol, heptanediol, octanediol, nonanediol, decanediol, and dodecanediol; alicyclic diols such as cyclohexanediol, and hydrogenated xylylene diol; and aromatic diols such as xylylene glycol. These can be used alone or in mixtures of two or more polyester-polyols.

Suitable isocyanate moieties can include, but are not limited to, 2,4 toluene di-isocyanate; 2,6 toluene di-isocyanate; isophorone di-isocyanate; xylene di-idocyanate; 4,4′-diphenylmethane di-isocyanate; methylene di-isocyanate; isopropylene di-isocyanate; lysine di-isocyanate; 2,2,4-trimethylhexamethylene di-isocyanate; 2,4,4-trimethylhexamethylene di-isocyanate; 1,6-hexamethylene di-isocyanate; methylcyclohexane di-isocyanate; isophorone di-isocyanate; 4,4′-dicyclohexylmethane di-isocyanate; and iso-propylidene cyclohexyl-4,4′-di-isocyanate. Suitable isocyanate moieties can also include, but are not limited to, biuret adducts, uretdione dimers, or isocyanurate trimers that contain at least one of the di-isocyanate compounds listed above, and mixtures thereof. Suitable isocyanate moieties can further include, but are not limited to pre-oligomerized forms of any of the preceding isocyanates partially reacted with polyols, and mixtures thereof.

To prevent cohesive failure upon hydrolysis of the polyester-polyol urethane adhesive an epoxy polymer is added. Suitable epoxy compounds include, but are not limited to di-glycidyl ethers; bis-phenol-A and its dimmers, trimers and higher oligomers; and tetra-glycidyl ethers of 1,1,2,2-tetra-phenol ethene and oligomers thereof, and mixtures thereof. Epoxy moieties can be described as having a suitable epoxy equivalent number. The epoxy equivalent number is defined as the mass of polymer which has one equivalent of reactivity, which is often the mass of polymer which corresponds to one mole of reactive side-chain groups. The epoxy equivalent weight is measured by the process described in ASTM D1652 (perchloric acid method) or can be more simply calculated as the molecular weight of the epoxy material in question divided by the number of epoxide groups. For example, Epon 828 (Hexion) is a di-glycidyl ether of bisphenol-A. It therefore has two epoxide groups, and a molecular weight of 340. The epoxy equivalent weight would then be 340/2=170 g/eq. Examples of suitable epoxy equivalent weights for an epoxy used in a composition of the present technology can include, for example, from about 100 g/eq to about 1000 g/eq, and from about 100 g/eq to about 200 g/eq. Preferably, the epoxy has an epoxy equivalent weight that is less than about 200 g/eq, and more preferably less than about 195 g/eq.

Compositions of the present technology can be formed by adding an epoxy, or an epoxy and a carbodiimide, to a polyol and an isocyanate that make up a polyurethane mixture. Without being bound by any particular theory, it is believed that the epoxy reacts with the polyurethane structure to reduce or eliminate the effects of the weak chain link of the carboxyl group, and that the carbodiimide could react with carboxylic acid produced by any subsequent hydrolysis to stabilize the polymer chain link. Although the epoxy, and the carbodiimide if used, can be added in any suitable order with respect to the polyol and the isocyanate, and with respect to each other, in some examples, the epoxy can be added after the formation of the polyurethane mixture, and the carbodiimide can be added after the epoxy.

In one example, the epoxy can be added after the after the polyol and the isocyanate have been combined and mixed for a desired period of time, such as for example, from about 1 minute to about 30 minutes, or from about 5 minutes to about 15 minutes, to form the polyurethane mixture. The epoxy can be present in an amount from about 1 part to about 40 parts epoxy to about 100 parts of polyurethane mixture, preferably from about 3 part to about 20 parts epoxy to about 100 parts of polyurethane mixture, and more preferably from about 5 part to about 15 parts epoxy to about 100 parts of polyurethane mixture. Preferably, the epoxy is a liquid epoxy, and can be a diglycidyl ether of bisphenol A grade (DGEBA), or a tetra-glycidyl ether of 1,1,2,2-tatra phenol ethane (TGATPE).

The carbodiimide can be present in an amount from about 1 part to about 10 parts carbodiimide to about 100 parts of the polyol, preferably from about 1 part to about 8 parts carbodiimide to about 100 parts of the polyol, and more preferably from about 1 part to about 4 parts carbodiimide to about 100 parts of the polyol. Preferably, the polycarbodiimide is Stabaxol™ P200 from Rhein Chemie Rheinau GmbH, which is a polymeric carbodiimide that is a reaction product of tetramethylxylene diisocyanate, and can be described as being a liquid polymeric tetramethylxylene-carbodiimide.

Examples of carbodiimide compounds that can be added to block the carboxylic acid end-groups formed by any hydrolysis reaction include, but are not limited to, N,N′-di-o-toluyl carbodiimide, N,N′-di-p-toluyl carbodiimide, N,N′-diphenyl carbodiimide, N,N′-di-2,6-dimethylphenyl carbodiimide, N,N′-bis(2,6-diisopropylphenyl) carbodiimide, N,N′-dioctyldecyl carbodiimide, N triyl,N′-cyclohexyl carbodiimide, N,N′-di-2,2-di-tert-butylphenyl carbodiimide, N triyl,N′-phenyl carbodiimide, N,N′-di-p-nitrophenyl carbodiimide, N,N′-di-p-aminophenyl carbodiimide, N,N′-di-p-hydroxyphenyl carbodiimide, and N,N′-di-cyclohexyl carbodiimide.

Once the epoxy, or the epoxy and the carbodiimide, have been added to the polyurethane mixture to form the composition, the composition can be used to form multilayer sheets, including photovoltaic backsheets. For example, a composition of the present technology can be applied to a polyethylene terephthalate (PET) substrate by any suitable processing, including, for example, conventional gravure coating processing. The composition can be dried on the PET substrate at a temperature of about 150° F. to about 200° F. to remove solvent. The PET with the composition dried thereto can then be laminated to a second substrate, including for example polyethylene (PE) or ethylene chlorotrifluoroethylene (ECTFE). Preferably, the multilayer sheet undergoes a post-curing process to allow sufficient time for completion of the primary urethane reaction and the secondary epoxy reaction, which can be at least about 48 hours.

Multilayer sheets, such as photovoltaic backsheets, including one or more layers of a composition of the present technology can have suitable initial adhesion, and can also resist hydrolysis under prolonged exposure to high heat and high humidity. For example, multilayer sheets including one or more layers of a composition of the present technology have an initial average bond strength of at least about 8 N/cm, and an average bond strength of at least about 4 N/cm after being subjected to a temperature of about 85° C. and a relative humidity of about 85% for a time period of at least about 2000 hours. Without being bound by any particular theory, it is believed that 2000 hours of exposure at 85° C. is equivalent to approximately 15 years exposure to 25° C. In some examples, the composition of the present technology will not hydrolyze until at or after about 3000 hours of being subjected to a temperature of about 85° C. and a relative humidity of about 85%.

Furthermore, it has also been found that the use of compositions with improved hydrolysis resistance of the present technology in photovoltaic backsheet structures having a PET core layer can also increase the hydrolytic resistance of the PET core layer such that it does not embrittle after testing the laminate at 85° C. and 85% relative humidity for 1500 hours or more. In contrast, such laminates constructed without the enhanced hydroltically stable composition of the present technology show destructive embrittlement of the core PET layer after testing the laminate at 85° C. and 85% relative humidity for 1500 hours or more.

### Example 1

### Composition Mixing Procedure

A composition of the present technology can be prepared by the following mixing procedure, wherein urethane part A is a polyol and urethane part B is a polyisocyanate:
1. Add 100 parts urethane part A into the mixing container;
2. Add ethyl acetate as a solvent to reduce the viscosity to from about 100 centipoises to about 300 centipoises;
3. Add 10 parts of urethane part B into the mixing container to form a polyurethane mixture;
4. Mix the polyurethane mixture for 10 minutes;
5. Add 10 parts of liquid epoxy to the polyurethane mixture in the container and continue mixing for additional 10 minutes; and
6. Add liquid carbodiimide in an amount of about 2 parts carbodiimide to 100 parts of the polyurethane mixture in the container and continue mixing for additional 10 minutes.

### Example 2

### Adhesive Hydrolysis Testing

Photovoltaic backsheets were tested at a temperature of about 85° C. and a relative humidity of about 85%. The photovoltaic backsheets each had a five layer construction as described above, having a first adhesive layer between the 1st outer layer and the core layer and a second adhesive layer between the 2nd outer layer and the core layer. The laminate structures, including the specific components of each tested adhesive layer are listed below as Table 1. The adhesive layers of Samples A, B and F did not contain epoxy or carbodiimide. The adhesive of Sample D contained epoxy, but not carbodiimide. The adhesive of sample E contained both epoxy and carbodiimide in accordance with the formulations of the present technology, and was formed in accordance with Example 1 above.

TABLE 1

| | | | | Adhesive System | | | |
|---|---|---|---|---|---|---|---|
| | Back Sheet Structures | | | (between core layer, and two outer layers) | | | |
| | 1^{st} outer | Core | 2^{nd} outer | Adhesive | Adhesive | Adhesive | Adhesive |
| Sample ID | layer | layer | layer | Component 1 | Component 2 | Component 3 | Component 4 |
| A | White | PET | White | Mitsui | Toluene di- | None | None |
| Comparative | ECTFE | | ECTFE | A515¹ | isocyanate | | |
| B | White | PET | White | Mitsui | iso-Phorone | None | None |
| Comparative | ECTFE | | ECTFE | A515 | di- | | |
| | | | | | isocyanate | | |
| C | White | PET | White | Mitsui | iso-Phorone | None | None |
| | PVdF | | PVdF | A515 | di- | | |
| | | | | | isocyanate | | |
| D | White | PET | White | Mitsui | iso-Phorone | 10 parts | None |
| | ECTFE | | ECTFE | A515 | di- | Epon 828² | |
| | | | | | isocyanate | | |
| E | White | PET | White | Mitsui | iso-Phorone | Epon 828 | Stabaxol |
| | ECTFE | | ECTFE | A515 | di- | | P200³ |
| | | | | | isocyanate | | |
| F | White | PET | White | Mitsui | iso-Phorone | Epon 834 | None |
| | ECTFE | | ECTFE | A515 | di- | | |
| | | | | | isocyanate | | |
| G | White | PET | White | Mitsui | iso-Phorone | Epon 1001 | None |
| | ECTFE | | ECTFE | A515 | di- | | |
| | | | | | isocyanate | | |
| H | White | PET | White | Mitsui | iso-Phorone | Epon 1031 | None |
| | ECTFE | | ECTFE | A515 | di- | | |
| | | | | | isocyanate | | |
| I | White | PET | White | DIC | DIC | None | None |
| Comparative | ECTFE | | ECTFE | TSB008C⁴ | TSH006C | | |
| J | White | PET | White | DIC | DIC | Epon 828 | None |
| | ECTFE | | ECTFE | TSB008C | TSH006C | | |
| K | White | PET | White | DIC | DIC | Epon 828 | Stabaxol |
| | ECTFE | | ECTFE | TSB008C | TSH006C | | P200 |
| L | White | PET | White | Mitsui | iso-Phorone | None | 2 parts⁵ |
| | ECTFE | | ECTFE | A515 | di- | | Stabaxol |
| | | | | | isocyanate | | P200 |
| M | White | PET | White | Mitsui | iso-Phorone | None | 4 parts⁵ |
| | ECTFE | | ECTFE | A515 | di- | | Stabaxol |
| | | | | | isocyanate | | P200 |
| N | White | PET | White | Mitsui | iso-Phorone | 5 parts | None |
| | ECTFE | | ECTFE | A515 | di- | Epon 828 | |
| | | | | | isocyanate | | |
| O | White | PET | White | Mitsui | iso-Phorone | 15 parts | None |
| | ECTFE | | ECTFE | A515 | di- | Epon 828 | |
| | | | | | isocyanate | | |

¹Mitsui A515 from Mitsui Chemicals America, Inc, Rye Brook, NY, USA
²Epon Resins from Hexion Specialty Chemicals, Epoxy Resins, Houston, TX
³Stabaxol P200 from Rhein Chemie Rheinau GmbH, Mannheim, Germany
⁴DIC TSB008C/TSH006C from Dainippon Ink Chemicals, Nihonbashi 3-chome, Chuo-ku, Tokyo, Japan
⁵weight/weight percentage based on adhesive component 1

The average bond strength of all samples for each type of photovoltaic backsheet was measured after 5 days of post curing at 100, prior to being subjected to the testing conditions (at 0 hours), and then after every 500 hours of being subjected to the testing conditions for a total testing duration of 2000 hours. The results are provided in Table 2 below.

TABLE 2

| Sample | Average Bond Strength (PET to Halar) N/cm | | | | |
|---|---|---|---|---|---|
| ID | 0 Hours | 500 Hours | 1000 Hours | 1500 Hours | 2000 Hours |
| A | 6.0 | 7.0 | 5.1 | 1.4 | 0.5 |
| B | 6.1 | 8.2 | 5.8 | 3.1 | 0.5 |
| C | 11.7 | 9.8 | 9.8 | 8.3 | 1.1 |
| D | 8.6 | 8.2 | 8.2 | 7.8 | 8.0 |
| E | 9.7 | 9.4 | 8.4 | 8.7 | 9.2 |
| F | 7.6 | 5.5 | 3.6 | 4.0 | 3.5 |
| G | 8.1 | 5.0 | 3.2 | 4.8 | 3.3 |
| H | 8.8 | 4.5 | 3.0 | 4.9 | 3.7 |
| I | 5.8 | 6.0 | 4.9 | 1.5 | 0.7 |
| J | 8.8 | 9.5 | 10.0 | 8.2 | 6.4 |
| K | 8.8 | 9.1 | 8.9 | 8.9 | 8.1 |
| L | 6.6 | 7.7 | 6.0 | 3.6 | 0.7 |
| M | 7.5 | 6.9 | 5.1 | 2.6 | 0.5 |
| N | 9.5 | 7.9 | 7.7 | 7.0 | 5.0 |
| O | 9.6 | 8.4 | 7.0 | 6.8 | 8.1 |

Sample A, Sample B and Sample I are comparative data points using two different polyester-polyols showing the loss of bond strength with extended exposure to damp heat. Sample A uses an aromatic di-isocyanate, whilst Sample B uses a more hydrolytically stable aliphatic di-isocyanate. Changing cross-linker appears to improve hydrolytic stability but only marginally. Sample C is a competitive photovoltaic backsheet shown here to illustrate the general behavior of the laminates to damp heat.

Samples D, F, G, H and J illustrate the effect of increasing the epoxy equivalent weight of the epoxy added.

The greatest effect on initial bond strength and the stability of that bond strength to long term damp heat exposure is best with a low molecular weight epoxy, as can be seen by comparing the results of Table 2 with the epoxy equivalent data provided below in table 3, and appears to be independent of the identity of the polyester-polyol or the isocyanate cross-linker based upon the results for sample J. Samples E and K show that further improvement in long term bond strength stability can be conferred by adding a low molecular weight epoxy and a carbodiimide, and that the improved results are independent of the identity of the polyol or the isocyanate cross-linker

TABLE 3

| | | | Bond strength after |
|---|---|---|---|
| | | | 2000 hrs at |
| | | Initial Bond | 85% RH, 85° C. |
| | | Strength (lb/in) | (lb/in) |
| | | Epoxy moiety with Mitsui A515 with | |
| Epoxy Equivalent | Epoxy | isophorone diisocyanate adhesive (1:1 | |
| Weight (g/eq) | Identity | ratio epoxy groups to urethane¹ groups)² | |
| 185-192 | Epon 828 | 8.4 | 7.7 |
| 195-230 | Epon 1031 | 9 | 4.2 |
| 255 | Epon 834 | 7.6 | 4.0 |
| 500 | Epon 1001 | 8.5 | 4.0 |

¹Urethane groups result from reaction of each isocyanate with an alcohol on the polyester polyol
²the results are the same at 2:1 and 1:2 ratio of epoxy to urethane groups

Samples L and M show the limited hydrolysis resistance afforded by using a carbodiimide alone as an additive. These samples can be viewed in comparison to the results for sample E where both a carbodiimide and an epoxy are used.

Samples N and O can be compared against sample J. Sample J contains 10 parts epoxy to 100 parts hydroxyl in the main polyol component. Sample N contains 5 parts epoxy to 100 parts hydroxyl in the main polyol component. Sample O contains 15 parts epoxy to 100 parts hydroxyl in the main polyol component. The peel strength data shows that there is little advantage to increasing the amount of epoxy additive.

Samples E and K show that further improvement in long term bond strength stability can be conferred by adding a low molecular weight epoxy and a carbodiimide, and that this effect is independent of the identity of the polyol or the isocyanate cross-linker

In general, the test results indicate that adding an epoxy to the polyol/isocyanate adhesive mixture can serve to increase initial bond strength and maintain the higher bond strength through hydrolysis.

Visual examination of the samples over time while being exposed to the testing conditions of 85° C. and a relative humidity of 85% are also of note. After prolonged exposure to the damp heat, it is often noticed that the PET core layer becomes brittle and will snap during the peal strength testing or on bending the laminate. Table 4 summarizes these observations on a selection of the samples discussed. In general, addition of epoxy moieties appears to stop the premature embrittlement of the PET core layer.

TABLE 4

| | Time at 85° C., 85% | | | | |
|---|---|---|---|---|---|
| Sample | 0 | 500 | 1000 | 1500 | 2000 |
| A | NO | NO | NO | YES | YES |
| B | NO | NO | NO | YES | YES |
| D | NO | NO | NO | NO | NO |
| E | NO | NO | NO | NO | NO |
| F | NO | NO | NO | NO | NO |
| G | NO | NO | NO | NO | NO |
| H | NO | NO | NO | NO | NO |
| I | NO | NO | NO | NO | NO |
| J | NO | NO | NO | NO | NO |
| K | NO | NO | NO | NO | NO |
| L | NO | NO | NO | NO | YES |
| M | NO | NO | NO | NO | NO |
| N | NO | NO | NO | NO | NO |
| O | NO | NO | NO | NO | NO |

Moreover, examination of the pealed surfaces leads to a further aspect of the conferred resistance to hydrolysis. It has been observed that at early stages in the exposure to damp heat the interfacial bond failure mode is typically due to the adhesive, meaning that the adhesive pulls away intact from one of the polymer film surfaces. After prolonged exposure this failure mode can change to a cohesive failure, meaning that the adhesive looses its internal strength and the failure leaves adhesive on both pealed film layers (e.g., the adhesive tears in the centre and splits). Examination of the failed adhesive for tackiness can indicate loss of molecular weight or plasticization by hydrolysis. In some instances where the adhesive is not protected from hydrolysis, the failure can become cohesive and the adhesive can become excessively tacky. Where the adhesive is protected, the failure mode stays adhesive, and the adhesive surface is dry and non-tacky. Table 5 summarizes these observations.

TABLE 5

| | Time (hours) at 85° C., 85% | | | | |
|---|---|---|---|---|---|
| | (Failure Mode, Condition of Exposed Adhesive layer) | | | | |
| Sample | 0 | 500 | 1000 | 1500 | 2000 |
| A | ADHESIVE | ADHESIVE | ADHESIVE | COHESIVE, | COHESIVE, |
| | | | | TACKY | YELLOW |
| | | | | | AND |
| | | | | | TACKY |
| B | ADHESIVE | ADHESIVE | ADHESIVE | COHESIVE, | COHESIVE, |
| | | | | TACKY | TACKY |
| D | ADHESIVE | ADHESIVE | ADHESIVE | ADHESIVE | ADHESIVE |
| E | ADHESIVE | ADHESIVE | ADHESIVE | ADHESIVE | ADHESIVE |
| F | ADHESIVE | ADHESIVE | ADHESIVE | ADHESIVE | ADHESIVE |
| G | ADHESIVE | ADHESIVE | ADHESIVE | ADHESIVE | ADHESIVE |
| H | ADHESIVE | ADHESIVE | ADHESIVE | ADHESIVE | COHESIVE, |
| | | | | | YELLOW |
| | | | | | ADHESIVE |
| I | ADHESIVE | ADHESIVE | COHESIVE | COHESIVE | COHESIVE, |
| | | | | | STICKY |
| J | ADHESIVE | ADHESIVE | ADHESIVE | ADHESIVE | ADHESIVE |
| K | ADHESIVE | ADHESIVE | COHESIVE | COHESIVE | COHESIVE, |
| | | | | | STICKY |
| L | ADHESIVE | ADHESIVE | ADHESIVE | COHESIVE, | COHESIVE, |
| | | | | STICKY | STICKY |
| M | ADHESIVE | ADHESIVE | ADHESIVE | COHESIVE, | COHESIVE, |
| | | | | STICKY | STICKY |
| N | ADHESIVE | ADHESIVE | ADHESIVE | ADHESIVE | ADHESIVE |
| O | ADHESIVE | ADHESIVE | ADHESIVE | ADHESIVE | ADHESIVE |

### Example 3

### Adhesive Hydrolysis Testing

Samples of multilayer sheets were placed in a testing chamber and subjected to pressurized steam conditions of 105° C. at a pressure of 1.05 atmospheres for a total of 240 hours. The average bond strength of the samples was measured periodically during the duration of the testing, and is provided in Table 6 below.

Each of the Samples was a backsheet for a photovoltaic cell that included a five layer laminated film of the structure illustrated in FIG. 1 that included a PET core layer, and polyurethane adhesive layers. The Control sample was PV 270 Honeywell Powershield™, available from Honeywell International Inc. Samples A and B were commercially available backsheets produced by other competitors in the field. Sample C was a backsheet having the same core and protective layers as the Control, but that included a composition of the present technology as the adhesive layers.

TABLE 6

| | | Average Bond Strength | | | | | |
|---|---|---|---|---|---|---|---|
| | | (PET to PE) N/15 mm* | | | | | |
| | | | 144 | 168 | 192 | 216 | 240 |
| Sample ID | Epoxy | 0 hr | hours | hours | hours | hours | hours |
| Control | None | 5.2 | 7.7 | 6.6 | 4.1 | 5.2 | 5.8 |
| A | None | 2.6 | 8.5 | 8.4 | 6.6 | 6.4 | 3.1 |
| B | None | 9.8 | 9.0 | 8.6 | 9.0 | 0.3 | 1.4 |
| C | Epon 828 | 10.5 | 15.0 | 14.1 | 10.0 | 9.2 | 9.6 |

As can be seen in Table 6 above, Sample C had a higher initial bond strength, and maintained a bond strength above 9 N/15 mm for the entire duration of the test. While all of the Samples had a bond strength higher than 6 N/15 mm after a period of 168 hours, the bond strengths of Samples A and B had fallen significantly after being subjected to the testing conditions for 240 hours.

### Example 4

### Moisture Vapor Transmission Rate Testing

The adhesive systems of Samples B and D as described in Example 2 above were applied to a sheet of 1 mil thick biaxially oriented nylon using a meyer rod. The side opposite the nylon in the nylon/adhesive system was then laminated to a non-woven fabric to cover the adhesive and avoid problems that could otherwise be caused by the tackiness of the adhesive during testing. The non-woven fabric was DuPont™ Sontara™ spunlace PET fabric commercially available from E. I. du Pont de Nemours and Company, which has a base weight of from about 43 g/m² to about 50 g/m². The non-woven fabric does not block moisture, and therefore did not have any impact upon the moisture vapor transmission rates (MVTR) of the laminate.

The laminates were then cured for 48 hours at room temperature. Test Sample X discussed below corresponds to the laminate constructed using the adhesive system of Sample B, and Test Sample Y discussed below corresponds to the laminate constructed using the adhesive system of Sample D.

The laminates of Test Samples X and Y were each constructed with two different adhesives coat weights (CW), as shown in Table 7 below. The adhesive coat weights were 5.07 g/cm² (3.11 lb/ream) and 10.07 g/cm² (6.30 lb/ream).

The laminates were mounted on a Mocon Permatran unit to test MVTR at standard conditions of 100° F. (37.8° C.) and 100% relative humidity (RH). The data is shown in Table 7.

TABLE 7

| | Structure | | | |
|---|---|---|---|---|
| | 1 mil Nylon/Adhesive/non-woven | | | |
| | Epoxy loading | | | MVTR for |
| | (dry wt % to | CW | MVTR | adhesive only |
| Description | polyol) | (g/cm²) | (g/m²/day) | g/m²/day |
| Test Sample X | 0% | 5.07 | 125.705 | 186.0 |
| | 0% | 10.27 | 118.11 | 170.5 |
| Test Sample Y | 10% | 5.07 | 143.375 | 227.85 |
| | 10% | 10.27 | 132.525 | 201.5 |

The MVTR for the adhesive only as listed in Table 7 above is a calculated number based upon the equation:

MVTR(adhesive)=1/(1/MVTR(laminate)−1/MVTR(nylon))

The MVTR of nylon having a thickness of 1 mil, as was used in test Samples X and Y is known to be 387.5 g/m²/day (25 g/100 in²/day) at 37.8° C. (100° F.) and 100% RH.

As can be seen from the results reported in Table 7 above, there was not a significant change in the MVTR between Test Sample X and Test Sample Y. Additionally, the results indicate that the MVTR is independent of adhesive coat weight. These results further indicate that the improvements in resistance to hydrolysis illustrated in Examples 2 and 3 with respect to the coatings of the present technology are not due to those coatings having increased moisture barrier properties.

From the foregoing, it will be appreciated that although specific examples have been described herein for purposes of illustration, various modifications may be made without deviating from the spirit or scope of this disclosure. It is therefore intended that the foregoing detailed description be regarded as illustrative rather than limiting, and that it be understood that it is the following claims, including all equivalents, that are intended to particularly point out and distinctly claim the claimed subject matter.

What is claimed is:

1. A composition comprising:
a polyol;
an isocyanate; and
an epoxy having an epoxy equivalent weight from about 100 g/eq to about 1000 g/eq.

2. The composition of claim 1, wherein the polyol and the isocyanate are mixed to form a polyurethane mixture.

3. The composition of claim 2, further comprising a carbodiimide.

4. The composition of claim 3, wherein the epoxy is present in an amount from about 1 part to about 40 parts epoxy to about 100 parts of polyurethane mixture, and the carbodiimide is present in an amount from about 1 part to about 10 parts carbodiimide to about 100 parts of the polyol.

5. The composition of claim 4, wherein the epoxy is present in an amount from about 3 part to about 20 parts epoxy to about 100 parts of polyurethane mixture, and the carbodiimide is present in an amount from about 1 part to about 8 parts carbodiimide to about 100 parts of the polyol.

6. The composition of claim 5, wherein the epoxy is present in an amount from about 5 part to about 15 parts epoxy to about 100 parts of polyurethane mixture, and the carbodiimide is present in an amount from about 1 part to about 4 parts carbodiimide to about 100 parts of the polyol.

7. The composition of claim 1, wherein the epoxy has an epoxy equivalent weight less than about 200 g/eq.

8. The composition of claim 1, wherein the epoxy is selected from the group consisting of di-glycidyl ethers; bis-phenol-A and its dimmers, trimers and higher oligomers; and tetra-glycidyl ethers of 1,1,2,2-tetra-phenol ethene and oligomers thereof, and mixtures thereof.

9. A multilayer sheet comprising:
a first layer;
a second layer having a first side and a second side; and
at least one layer of a composition comprising a polyol, an isocyanate, and an epoxy having an epoxy equivalent weight from about 100 g/eq to about 1000 g/eq, wherein a layer of the composition adheres the first layer to the first side of the second layer to form the multilayer sheet, and the average bond strength of the multilayer sheet is at least about 8 N/cm as measured at a time about 48 hours after the formation of the multilayer sheet.

10. The multilayer sheet of claim 9, further comprising:
at least one third layer, and
at least one second layer of the composition, wherein the second layer of the composition adheres the at least one third layer to the second side of the at least one second layer.

11. The multilayer sheet of claim 9, wherein the average bond strength of the multilayer sheet is at least about 4 N/cm as measured after the multilayer sheet has been subjected to a temperature of about 85° C. and a relative humidity of about 85% for a time period of at least about 2000 hours.

12. The multilayer sheet of claim 9, wherein the composition further comprises a carbodiimide.

13. A backsheet for a photovoltaic cell comprising the multilayer sheet of claim 9.

14. The backsheet for a photovoltaic cell of claim 13, wherein the multilayer sheet further comprises:
at least one third layer, and
at least one second layer of the composition, wherein the second layer of the composition adheres the at least one third layer to the second side of the at least one second layer.

15. A method of improving the hydrolytic stability of a multilayer sheet, the method comprising:
providing a polyol;
providing an isocyanate;
mixing the polyol and the isocyanate to form a polyurethane mixture;
adding an epoxy having an epoxy equivalent weight from about 100 g/eq to about 1000 g/eq to the polyurethane mixture to form a composition; and
forming a multilayer sheet comprising at least one layer of the composition.

16. The method of claim 15, further comprising:
adding a carbodiimide to the polyurethane mixture.

17. The method of claim 16, wherein the epoxy is present in an amount from about 1 part to about 40 parts epoxy to about 100 parts of polyurethane mixture, and the carbodiimide is present in an amount from about 1 part to about 10 parts carbodiimide to about 100 parts of the polyol.

18. The method of improving the hydrolytic stability of a multilayer sheet of claim 15, wherein the average bond strength of the multilayer sheet is at least about 4 N/cm as measured after the multilayer sheet has been subjected to a temperature of about 85° C. and a relative humidity of about 85% for a time period of at least about 2000 hours.

19. A photovoltaic cell comprising a backsheet comprising:
at least one layer of a composition comprising a polyol, an isocyanate, an epoxy having an epoxy equivalent weight from about 100 g/eq to about 1000 g/eq, and optionally a carbodiimide.

20. The photovoltaic cell of claim 19, wherein the average bond strength of the multilayer sheet is at least about 4 N/cm as measured after the multilayer sheet has been subjected to a temperature of about 85° C. and a relative humidity of about 85% for a time period of at least about 2000 hours.

21. The photovoltaic cell of claim 19, wherein the average bond strength of the multilayer sheet is at least about 8 N/cm as measured at a time about 48 hours after the formation of the multilayer sheet.

22. A method of adhering substrates, the method comprising:
providing a first substrate;
providing a second substrate; and
applying a layer of a composition between the first substrate and the second substrate to adhere the first substrate to the second substrate;
wherein the composition comprises a polyol, an isocyanate, and an epoxy having an epoxy equivalent weight from about 100 g/eq to about 1000 g/eq.
